(19) United States
(12) Patent Application Publication
(10) Pub. No.: US 2022/0359213 A1
(43) Pub. Date: Nov. 10, 2022

(54) METHOD FOR FABRICATING SEMICONDUCTOR CHIP STRUCTURES, SEMICONDUCTOR CARRIER AND SEMICONDUCTOR CHIP STRUCTURE

(71) Applicant: PanelSemi Corporation, New Taipei City (TW)

(72) Inventor: Tang-Chin HUNG, New Taipei City (TW)

(21) Appl. No.: 17/735,367

(22) Filed: May 3, 2022

Related U.S. Application Data
(60) Provisional application No. 63/183,845, filed on May 4, 2021.

(51) Int. Cl. H01L 21/304; H01L 21/78; H01L 21/18

(52) U.S. Cl. CPC H01L 21/3043; H01L 21/78; H01L 21/187

(57) ABSTRACT

A method for fabricating semiconductor chip structures, which comprises steps of: providing plural slice units tiled with one another on a process carrier, wherein each slice unit is made from a wafer and includes a substrate with an outline, and a gap is formed between adjacent two of the slice units; planarizing tops of the slice units; accomplishing circuits on the slice units and turning them into circuited slice units; and forming plural semiconductor chip structures individually with each other by at least breaking down the circuited slice units; wherein a planar size of one slice unit is no less than that of a corresponding semiconductor chip structure, or the planar size of one slice unit is no less than multiple of the planar size of the corresponding semiconductor chip structure. A semiconductor carrier and a semiconductor chip structure made by the method are also provided.

### CROSS REFERENCE TO RELATED APPLICATIONS

The non-provisional patent application claims priority to U.S. provisional patent application with Ser. No. 63/183,845 filed on May 4, 2021. This and all other extrinsic materials discussed herein are incorporated by reference in their entirety.

### BACKGROUND

### Technology Field

This disclosure relates to a method for fabricating semiconductor chip structures, a semiconductor carrier and a semiconductor chip structure.

### Description of Related Art

There is a global shortage of semiconductor supply in the market, especially in computer chips. Consumers are facing price rises and shortages of products from TVs and mobile phones to cars and games consoles as a global shortage in semiconductors grows under the fact that chip is the brain of everything. As the production is back to normal from temporary delay due to coronavirus pandemic, a new surge in demand driven by changing habits due to the pandemic means that it is now reaching crisis point. However, there is no sign of supply catching up, or demand decreasing.

Therefore, a semiconductor chip structure and a method of making the same, in an effective and efficient manner, is in urge.

### SUMMARY

One or more exemplary embodiment of this disclosure is to provide a method of fabricating semiconductor chip structures in an effective and efficient manner, and the semiconductor carrier and semiconductor chip structure made by the method.

In an exemplary embodiment, a method for fabricating semiconductor chip structures includes the following steps of: providing a plurality of slice units tiled with one another on a surface of a process carrier, wherein each of the slice units is made by a wafer and includes a substrate with an outline, and a gap is formed between adjacent two of the slice units; planarizing tops of the slice units; accomplishing circuits on the slice units and turning the slice units into a plurality of circuited slice units; and forming a plurality of semiconductor chip structures individually with each other by at least breaking down the circuited slice units. The planar size of a corresponding one of the slice units is no less than the planar size of the corresponding one of the chip structures, or the planar size of the corresponding one of the slice units is no less than multiple of the planar size of the corresponding one of the semiconductor chip structures.

In the above method, in the step of providing the slice units on the process carrier, wherein the substrate is a single-crystal silicon substrate, a poly-crystal silicon substrate, a SOI (silicon on insulator) substrate, a SiC (Silicon Carbide) substrate, a Sapphire substrate, a III-V compound substrate, an II-VI compound substrate, or a compound substrate.

In the above method, in the step of providing the slice units on the process carrier, wherein the III-V compound substrate includes GaAs (Gallium-Arsenide), GaN (Gallium Nitride), InP (Indium Phosphide), GaP (Gallium Phosphide), GaSb (Gallium Antimonide), InAs (Indium Arsenide), or InSb (Indium Antimonide).

In the above method, in the step of providing the slice units on the process carrier, wherein the II-VI compound substrate includes CdTe (Cadmium-Telluride), CdS (Cadmium-Sulfide), ZnTe (Zinc telluride), ZnSe (Zinc Selenide), or ZnS (Zinc Sulphide).

In the above method, in the step of providing the slice units on the process carrier, wherein the compound substrate includes CuInSe2 (CIS, Copper Indium Selenide) or CIGS (Copper Indium Gallium Selenide).

In the above method, in the step of providing the slice units on the process carrier, wherein the process carrier is a glass substrate.

In the above method, in the step of providing the slice units on the process carrier, wherein the slice units and the process carrier are bounded directly.

In the above method, in the step of providing the slice units on the process carrier, wherein the slice units and the process carrier are bounded directly by an anodic bonding, a fusion bonding, or a direct bonding.

In the above method, in the step of providing the slice units on the process carrier, wherein the slice units and the process carrier are bounded indirectly through an intermediate material.

In the above method, in the step of providing the slice units on the process carrier, wherein the slice units and the process carrier are bounded indirectly by an adhesive bonding, a glass-frit bonding, a low-melting glass bonding, a metal bonding, a eutectic bonding, or a dielectric bonding.

In the above method, in the step of providing the slice units on the process carrier, wherein the slice units and the process carrier are bounded indirectly via an adhesive, In (Indium), Sn (Tin), low-melting glasses of SnO—ZnO—P2O5.

In the above method, in the step of providing the slice units on the process carrier, wherein a coefficient of thermal expansion (CTE) of the adhesive is as same as (close to) a CTE of the substrate.

In the above method, in the step of providing the slice units on the process carrier, wherein the adhesive is a de-bonding layer.

In the above method, in the step of providing the slice units on the process carrier, wherein the adhesive is made of PI (Polyimide).

In the above method, in the step of providing the slice units on the process carrier, wherein the quantity of the adhesive is plural, and the adhesives respectively connect the slice units.

In the above method, in the step of providing the slice units on the process carrier, wherein the quantity of the adhesive is single, and the adhesives connect the slice units.

In the above method, before the step of providing the plural of slice units on the process carrier, further comprising: cutting each of the slice units into a plural of chip units, and holding the outlines of the slice units kept, wherein a planar size of one of the chip units is equal to the planar size of the corresponding one of the semiconductor chip structures.

In the above method, before the step of cutting each of the slice units into a plural of chip units, further comprising: taping a film on a bottom face each of the slice units.

In the above method, in the step of taping the film, wherein a size of each of the chip units is equal to the size of each of the semiconductor chip structures.

In the above method, in the step of providing the slice units on the process carrier, wherein the corresponding one of the slice units sharing a co-center with the wafer.

In the above method, in the step of providing the slice units on the process carrier, the outline of the substrate is defined as a polygon outline.

In the above method, before the step of providing the slice units on the process carrier, wherein the polygon outline of each of the slice units is quadrilateral, pentagonal, hexagonal, or octagonal.

In the above method, before the step of providing the slice units on the process carrier, further comprising: cutting each of the slice units and forming the outline from a rounded one to a polygon one.

In the above method, before the step of providing the slice units on the process carrier, wherein a planar size of the process carrier is no less than multiple of the planar size of each of the slice units.

In the above method, before, in, or after the step of providing the slice units on the process carrier, further comprising: grinding the substrate of a corresponding one of the slice units.

In the above method, in the step of providing the slice units on the process carrier, wherein the substrate of each of the slice units defines a thickness, which is greater than 0.4 mil (10 nm) or is no greater than 100 μm.

In the above method, in the step of providing the slice units on the process carrier, wherein the thickness of the substrate of each of the slice units ranges from 40 nm to 60 nm.

In the above method, in the step of providing the slice units on the process carrier, wherein a planar size of the substrate of each of the slice units equals to one another.

In the above method, in the step of planarizing tops of the slice units, further comprising: filling a sealing material in the gap between the adjacent two of the slice units.

In the above method, in the step of filling the sealing material in the gap, wherein the sealing material is a passivation layer.

In the above method, in the step of filling the sealing material in the gap, wherein the passivation layer is made of silicon oxide (SiOx), or/and silicon nitride (SiNx).

In the above method, in the step of filling the sealing material in the gap, wherein the passivation layer is made of Al₂O₃, SiO₂, Ta₂O₅ or TiO₂, or any combination of foresaid materials.

In the above method, in the step of filling the sealing material in the gap, a coefficient of thermal expansion (CTE) of the sealing material is as same as the CTE of the substrate.

In the above method, in the step of filling the sealing material in the gap, the Coefficient of thermal expansion (CTE) of the sealing material is no greater than 10 ppm/K or no less than 0.01 ppm/K.

In the above method, in the step of filling the sealing material in the gap, the Coefficient of thermal expansion (CTE) of the sealing material ranges from 2.5 to 6 ppm/K.

In the above method, in the step of filling the sealing material in the gap, wherein the sealing material is coated on the substrate and the gap via Spin-on-Glass (SOG) process, or a Spin-on-Dopant (SOD) process.

In the above method, after the step of filling the sealing material in the gap, further comprising: grinding the top surfaces of the slice units to a coplanar defined together.

In the above method, in the step of filling the sealing material in the gap, further comprising: covering a passivation layer above the sealing material.

In the above method, in the step of grinding to a coplanar of the slice units, wherein the passivation layer is kept covering the sealing material while the coplanar is formed.

In the above method, before the step of accomplishing the circuited, wherein the substrate of each of the slice units is a bare substrate without circuits, or a work-in-process substrate with partial circuits.

In the above method, in the step of accomplishing the circuited, wherein the circuited process includes evaporation or deposition, lithography, annealing, spin on glass, or doping (diffusion or ion implantation), or any combination of foresaid steps.

In the above method, before or in the step of forming the semiconductor chip structures, further comprising: dicing the circuited slice units to define an outline of the semiconductor chip structures by laser treatment with a boundary notch.

In the above method, in the step of dicing the circuited slice units, wherein the semiconductor chip structures of a corresponding one of the circuited slice units are connected with each other as a whole and then breaking down to the semiconductor chip individually.

In the above method, in the step of dicing the circuited slice units, wherein the semiconductor chip structures of a corresponding one of the circuited slice units are directly breaking down to the semiconductor chip individually.

In the above method, in the step of forming the semiconductor chip structures, wherein a planar size of the semiconductor chip structures equals to each other.

In the above method, in the step of forming the semiconductor chip structures, wherein a quantity of the circuited chip units is greater than one hundred.

In the above method, in the step of forming the semiconductor chip structures, wherein the quantity of the circuited chip units is greater than one thousand.

In the above method, in the step of forming the semiconductor chip structures, wherein each of the semiconductor chip structure further includes a corresponding part of the process carrier.

In the above method, in the step of forming the semiconductor chip structures, further comprising: removing the process carrier from the semiconductor chip structures before the semiconductor chip structures dividing individually.

In the above method, in the step of forming the semiconductor chip structures, wherein each of the semiconductor chip structure includes a transistor.

In the above method, in the step of forming the semiconductor chip structures, wherein the transistor is a thin-film transistor (TFT) or/and a Complementary Metal-Oxide-Semiconductor (CMOS).

In the above method, in the step of forming the semiconductor chip structures, wherein the corresponding one of the semiconductor chip structures is a power management intergraded circuit (PMIC).

In the above method, in the step of forming the semiconductor chip structures, wherein each of the semiconductor chip structures further includes a corresponding part of the process carrier.

In the above method, in the step of forming the semiconductor chip structures, wherein the corresponding one of the semiconductor chip structures is a chip with a set of circuits or with a system of integrated circuits.

In another exemplary embodiment, a semiconductor carrier includes a process carrier and a plurality of slice units. The slice units are connected on a surface of the process carrier and tiled with one another. Each of the slice units includes a substrate with an outline, and a gap is formed between adjacent two of the slice units. Each slice unit is made by a wafer, and the coefficient of thermal expansion (CTE) of the process carrier approaches that of the substrate.

In one embodiment, each of the slice units defines a circumscribed circle sharing a co-center with the wafer.

In one embodiment, the semiconductor carrier further includes an adhesive formed between the slice units and the process carrier.

In one embodiment, the adhesive is made of PI (Polyimide).

In one embodiment, the process carrier is made of glass.

In one embodiment, the substrate of each of the slice units is a bare substrate.

In one embodiment, the tops of the slice units are planarized.

In one embodiment, one or more of the circuited slice units include a thin film circuit.

In one embodiment, one or more of the circuited slice units include a transistor.

In one embodiment, the slice units are accomplished with circuits to be a plurality of circuited slice units.

In another exemplary embodiment, a semiconductor chip structure is formed by turning the circuited slice units into pieces individually with each other.

As mentioned above, the method for fabricating semiconductor chip structures of this disclosure includes steps of: providing a plurality of slice units, each of which is made by a wafer, on a process carrier; accomplishing circuits on the slice units; and breaking down the circuited slice units to form a plurality of semiconductor chip structures individually with each other. Herein, the planar size of a corresponding one of the slice units is no less than the planar size of the corresponding one of the semiconductor chip structures, or the planar size of the corresponding one of the slice units is no less than multiple of the planar size of the corresponding one of the semiconductor chip structures. In addition, the semiconductor carrier and semiconductor chip structure can be made by the above-mentioned method. Accordingly, the method of this disclosure can fabricate the semiconductor carrier and the semiconductor chip structures in an effective and efficient manner. The present disclosure has the benefit of, but not objective-oriented as, variety of products, budget control of manufacture, requirements meeting of different application.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1 is a flow chart of a method of fabricating semiconductor chip structures according to an embodiment of this disclosure;

FIG. 2A is a top view of a semiconductor carrier according to an aspect of this disclosure;

FIG. 2B is a schematic diagram showing chip units predetermined in the slice unit as shown in FIG. 2A;

FIG. 3A is a top view of a semiconductor carrier according to another aspect of this disclosure;

FIG. 3B is a schematic diagram showing chip units predetermined in the slice unit as shown in FIG. 3A;

FIG. 4A is a top view of a semiconductor carrier according to another aspect of this disclosure;

FIG. 4B is a schematic diagram showing chip units predetermined in the slice unit as shown in FIG. 4A;

FIG. 5 is a top view showing slice units tiled with one another on the surface of the process carrier;

FIG. 6A is a cross-sectional profile of the slice units of FIG. 5 along the line AA, wherein the slice units are arranged on one single adhesive layer; and

FIG. 6B is a cross-sectional profile of the slice units of FIG. 5 along the line AA, wherein the slice units are arranged on different adhesive layers, respectively.

### DETAILED DESCRIPTION OF THE DISCLOSURE

The present disclosure will be apparent from the following detailed description, which proceeds with reference to the accompanying drawings, wherein the same references relate to the same elements.

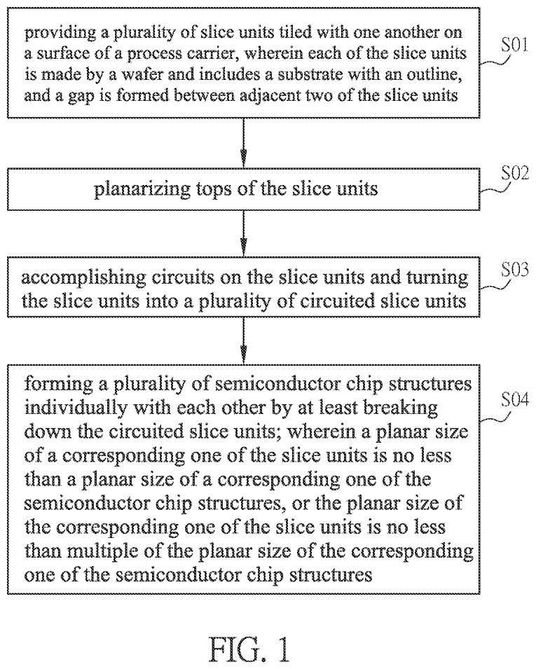

This disclosure relates to a method for fabricating semiconductor chip structures in an effective and efficient manner, including at least four main processes, procedures, or stages. As shown in FIG. 1, the method for fabricating semiconductor chip structures includes the following steps of: (a) providing a plurality of slice units tiled with one another on a surface of a process carrier, wherein each of the slice units is made by a wafer and includes a substrate with an outline, and a gap is formed between adjacent two of the slice units (step S01); (b) planarizing tops of the slice units (step S02); (c) accomplishing circuits on the slice units and turning the slice units into a plurality of circuited slice units (step S03); and (d) forming a plurality of semiconductor chip structures individually with each other by at least breaking down the circuited slice units; wherein a planar size of a corresponding one of the slice units is no less than a planar size of a corresponding one of the semiconductor chip structures, or the planar size of the corresponding one of the slice units is no less than multiple of the planar size of the corresponding one of the semiconductor chip structures (step S04). In some cases, the planar size of a corresponding one of the slice units could equal to the planar size of a corresponding one of the semiconductor chip structures, or the planar size of the corresponding one of the slice units could be multiple of the planar size of the corresponding one of the semiconductor chip structures

Some aspects and embodiments of this disclosure will be described hereinafter.

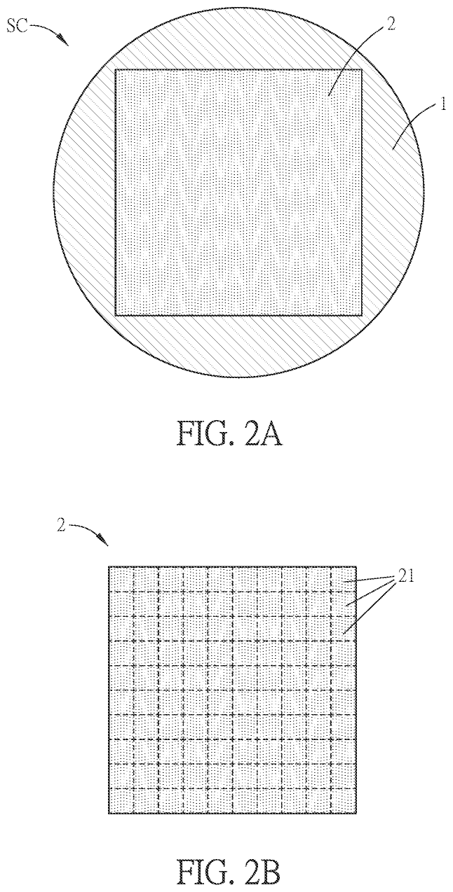

In the step S01, each slice unit 2 is made by a wafer, and the coefficient of thermal expansion (CTE) of the process carrier 1 approaches (or substantially equal to) that of the substrate of the slice unit 2. In one embodiment, the structure of the process carrier 1 and the slice units connected thereon can be realized as a semiconductor carrier SC (as shown in FIGS. 2A, 3A and 4A).

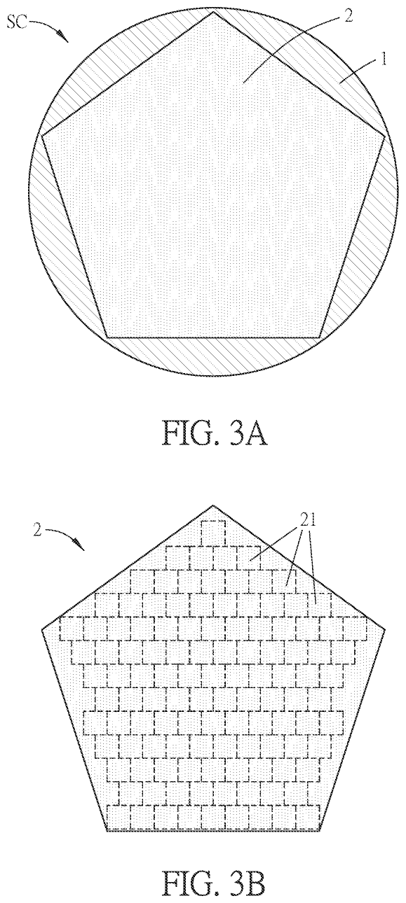

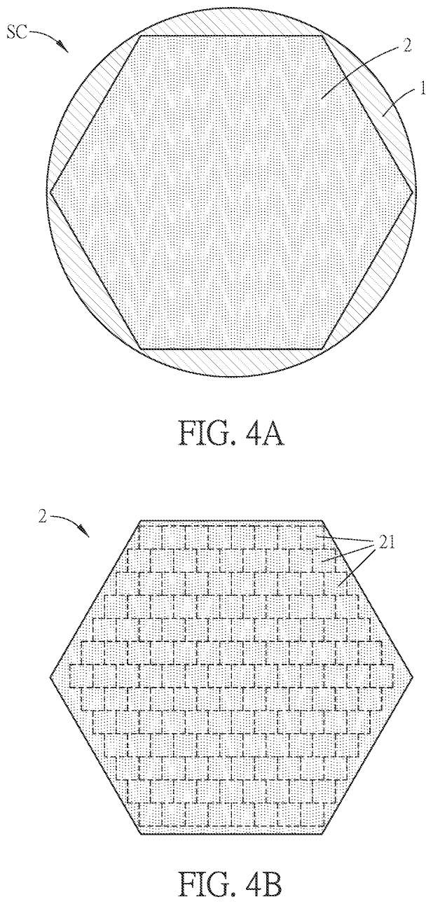

In the step S01, a plurality of slice units 2 tiled with one another are arranged on a surface of the process carrier 1, and the outline of the substrate of each of the slice units 2 can be rounded or polygon. As shown in FIGS. 2A and 2B, the outline of the substrate of the slice unit 2 is quadrilateral (e.g. square). As shown in FIGS. 3A and 3B, the outline of the substrate of the slice unit 2 is pentagonal. As shown in FIGS. 4A and 4B, the outline of the substrate of the slice unit 2 is hexagonal.

In one embodiment, the substrate can be, for example but not limited to, a single-crystal silicon substrate, a poly-crystal silicon substrate, a SOI (silicon on insulator) substrate, a IV-IV compound substrate, a Sapphire substrate, a III-V compound substrate, an II-VI compound substrate, or a compound substrate. For example, the IV-IV compound substrate can be a SiC (Silicon Carbide) substrate. The III-V compound substrate can be a GaAs (Gallium-Arsenide) substrate, a GaN (Gallium Nitride) substrate, an InP (Indium Phosphide) substrate, a GaP (Gallium Phosphide) substrate, a GaSb (Gallium Antimonide) substrate, an InAs (Indium Arsenide) substrate, or an InSb (Indium Antimonide) substrate. The II-VI compound substrate can be a CdTe (Cadmium-Telluride) substrate, a CdS (Cadmium-Sulfide) substrate, a ZnTe (Zinc telluride) substrate, a ZnSe (Zinc Selenide) substrate, or a ZnS (Zinc Sulphide) substrate. The compound substrate can be a CuInSe₂ (CIS, Copper Indium Selenide) substrate or a CIGS (Copper Indium Gallium Selenide) substrate. The materials the mentioned above are options for describing of making the substrate, but not for limited.

In one embodiment, the process carrier 1 can be, for example but not limited to, a glass substrate. In other embodiments, the process carrier 1 can be made of other material with a CTE approaching (or substantially equal to) that of the selected substrate.

In one embodiment, the slice units 2 and the process carrier 1 can be bounded directly or indirectly. In one aspect, the slice units 2 and the process carrier 1 can be bounded directly by, for example, an anodic bonding, a fusion bonding, or a direct bonding. In another aspect, the slice units 2 and the process carrier 1 can be bounded indirectly through an intermediate material.

As mentioned above, in the aspect of indirectly bonding, the slice units 2 and the process carrier 1 can be bounded indirectly by, for example but not limited to, an adhesive bonding, a glass-frit bonding, a low-melting glass bonding, a metal bonding, an eutectic bonding, or a dielectric bonding. To be elaborated, the slice units 2 and the process carrier 1 can be bounded indirectly via an adhesive, metal In (Indium), metal Sn (Tin), or low-melting glasses of SnO—ZnO—P₂O₅. The CTE of the adhesive is close to, preferably as same as, the CTE of the substrate. In addition, the adhesive can be a de-bonding layer, such as for example but not limited to, a PI (Polyimide) material. In practice, the adhesive can be implemented in a vacuum chamber.

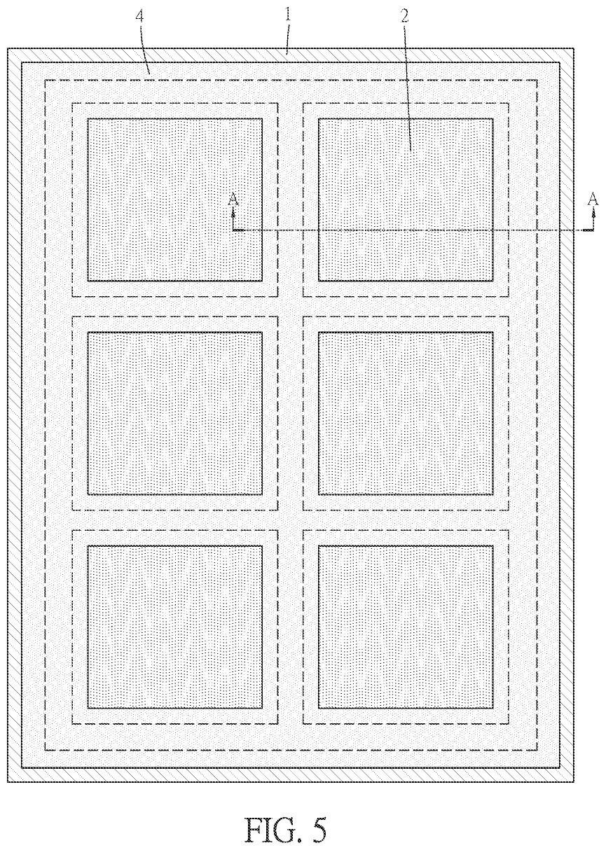

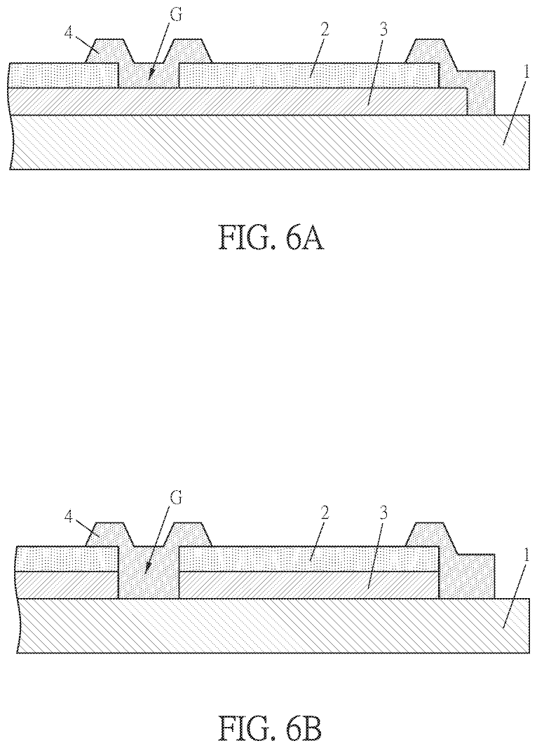

FIG. 5 is a top view showing slice units 2 tiled with one another on the surface of the process carrier 1; FIG. 6A is a cross-sectional profile of the slice units 2 of FIG. 5 along the line AA, wherein the slice units 2 are arranged on one single adhesive layer 3; and FIG. 6B is a cross-sectional profile of the slice units 2 of FIG. 5 along the line AA, wherein the slice units 2 are arranged on different adhesive layers 3, respectively.

As shown in FIG. 6A, when the slice units 2 and the process carrier 1 are bounded indirectly by an adhesive bonding, the adhesive can form a single adhesive layer 3, which can connect multiple or all of the slice units 2 for indirectly bonding the multiple or all of the slice units 2 to the process carrier 1. As shown in FIG. 6B, when the slice units 2 and the process carrier 1 are bounded indirectly by an adhesive bonding, the adhesive can form a plurality of adhesive layers 3, which can connect the slice units 2 respectively (e.g. in a one-to-one manner) for indirectly bonding the slice units 2 to the process carrier 1.

In one embodiment, each of the slice units 2 can optionally further include a plurality of chip units 21 predetermined but still hold the outline thereof. As shown in FIGS. 2B, 3B and 4B, each slice unit 2 includes a plurality of predetermined chip units 21, and the outline of the slice unit 2 is still remained. The outline can be, for example but not limited to, a quadrilateral outline (see FIG. 2B), a pentagonal outline (see FIG. 3B), or a hexagonal outline (see FIG. 4B).

In one embodiment, the outline of the substrate may be defined with a polygon outline, wherein the polygon outline of each of the slice units 2 is quadrilateral, pentagonal, hexagonal, or octagonal, but this disclosure is not limited thereto.

In one embodiment, as shown in FIGS. 5, 6A and 6B, in the adjacent two of the slice units 2, a straight side of a corresponding one of the slice units 2 neighbors with a straight side of the other one. To be elaborated, the corresponding one of the slice units 2 defines a circumscribed circle sharing a co-center with the wafer, especially the corresponding one of the slice units 2 may equal to or constrained within a circle of a diameter of 6, 8, or 12 inches. The polygon outline of the substrate may be constrained within a diameter of a 6-inch, 8-inch, or 12-inch wafer, while the substrate with the rounded outline may be the 6-inch, 8-inch, or 12-inch wafer per se. To be noted, the size of the wafer is not limited.

In one embodiment, before or in the step S01, the method further includes a step of cutting each of the slice units 2 and forming the outline from a rounded one to a polygon one. In addition, before the step of cutting each of the slice units 2 into a plurality of chip units 21, the method can further include a step of: taping a film on a bottom face of each slice unit 2.

In one embodiment, the size of each of the chip units 21 can be optionally equal to the size of each of the semiconductor chip structures or not, and it depends on how the maximum extent of the flexibility of the design and the utilization of the wafer (substrate) is. In this case, the size of each of the chip units 21 is equal to the size of each of the semiconductor chip structures, but this disclosure is not limited thereto.

In one embodiment, the substrate of each slice unit 2 is of a thickness, greater than 0.4 mil (10 nm) and is not greater than 100 μm. More specifically, the thickness of the substrate of each slice unit 2 can range from 40 nm to 60 nm. For example, the substrate made from the SOI wafer is capable of offering the thickness from 40 nm to 60 nm. In this stage, the slice unit 2 can be formed as the original size of the wafer, or an after-cut size of the wafer. If the planar size of the slice unit 2 can be trimmed to be less than the planar size of the process carrier 1 but greater than the planar size of the semiconductor chip structure, it would accelerate the whole manufacturing process of the semiconductor chip structures and increase the coverage of the effective working area thereof. If the planar size of the slice unit 2 can be trimmed to as same as the planar size of the semiconductor chip structure, it would provide the final size at the beginning of the whole manufacturing process thereof for varieties.

The method of this embodiment further includes, before the step S01, a step of cutting each of the slice units 2 into a plurality of chip units 21, and holding the outlines of the slice units kept, wherein the planar size of each of the chip units 21 is close to, preferably equal to, the planar size of the corresponding one of the semiconductor chip structures. In other words, the planar size of one of the chip units 21 is no less than the planar size of the corresponding one of the semiconductor chip structures; in general, the planar size of one of the chip units 21 is substantially equal to, for example slightly larger than, the planar size of the corresponding one of the semiconductor chip structures.

In one embodiment, the size of each of the chip units 21 is equal to the size of each of the semiconductor chip structures. Before or in the step S01, the planar size of the process carrier 1 is equal to the multiple of the planar size of each of the slice units 2 for containing the slice units 2.

Before, in or after the step S01, the method of this embodiment further includes a step of: grinding the substrate of a corresponding one of the slice units 2.

The planar size of the substrate of each of the slice units 2 can be optionally equal to one another or not. In one embodiment, the planar size of the substrate of each of the slice units 2 is equal to one another, but this disclosure is not limited thereto.

In the step S02, referring to FIGS. 5, 6A and 6B, the method of this embodiment further includes a step of: filling a sealing material in the gap G between the adjacent two of the slice units 2.

In the step S02, the sealing material is, for example but not limited to, a passivation layer 4 as illustrated in FIGS. 5, 6A and 6B.

In the step S02, the sealing material can be formed on the substrate and between the gap G by a planarization process. In one embodiment, the planarization process can be, for example but not limited to, a Spin-on-Glass (SOG) process or a Spin-on-Dopant (SOD) process. The formed passivation layer 4 can be made of, for example but not limited to, silicon oxynitride (SiOxNy), silicon oxide (SiOx), or/and silicon nitride (SiNx). To be noted, the material of the passivation layer 4 is not limited to the above-mentioned materials. In other embodiments, the passivation layer 4 can be made of, for example but not limited to, Al₂O₃, SiO₂, Ta₂O₅, TiO₂, or Al₂O₃, or any combination of foresaid materials.

In the step S02, the coefficient of thermal expansion (CTE) of the sealing material is slightly appropriate as, equivalent to, close to, or as same as the CTE of the substrate. Furthermore specifically, the CTE of the sealing material can be selected to meet the glass or SOI wafer. For example, but not limited, the CTE of the sealing material is not greater than 10 ppm/K and not less than 0.01 ppm/K. More specifically, the CTE of the sealing material ranges from 2.5 to 6 ppm/K.

In the step S02, the method of this embodiment further includes, after the step of filling the sealing material in the gap G, a step of: grinding the top surfaces of the slice units 2 to a coplanar surface defined together. For more details, each of the slice units 2 may have one or more top surfaces, and the coplanar surface defined by all of the slice units 2 can be defined by the topmost surfaces of all of the slice units 2.

As motioned foresaid, the passivation layer 4 can be applied above the sealing material for covering. When implementation of the grinding step, the passivation layer 4 is kept covering the sealing material while the coplanar surface is formed.

Before or in the step S03, the substrate of each of the slice units 2 can be a bare substrate without circuits, or a work-in-process substrate with partial circuits.

In the step S03, the circuited process includes an evaporation process or deposition process, a lithography process, an annealing process, a flattening process, or a doping process, or any combination of foresaid processes or steps. In more details, the deposition process can be, for example but not limited to, Plasma-enhanced chemical vapor deposition (PECVD)), the lithography process (also called optical lithography or UV lithography) at least includes masking, optical exposing and etching, the flattening process can be, for example but not limited to, spin on glass or spin on dopant, and the doping process can be, for example but not limited to, diffusion or ion implantation. In one embodiment, the accomplished circuits can include the thin-filmed traces or/and transistors, but this disclosure is not limited thereto.

Before or in the step S04, the method of this embodiment further includes a step of: dicing the circuited slice units to define an outline of the semiconductor chip structures by laser treatment with a boundary notch. In one embodiment, the semiconductor chip structures of a corresponding one of the circuited slice units are connected with each other as a whole, and then the whole structure is broken down to the semiconductor chip structures individually. In an optional manner, one of the circuited slice units are directly broken down to form the semiconductor chip structures individually.

For more details, the outlines of the semiconductor chip structures can be determined with the steps S01 to S04, or even before the step S01. No matter when or how to define the outlines of the semiconductor chip structures, it would go into pieces at the end of the step S04. In addition, the outline of the slice units, defined with multiple of the semiconductor chip structures, is equivalent to the embodiment of this disclosure.

In the step S04, the planar sizes of the semiconductor chip structures can optionally equal to each other or not. In one embodiment, the planar sizes of the semiconductor chip structures are equal to each other. In other embodiments, the semiconductor chip structures can have different planar sizes. In other embodiments, a part of the semiconductor chip structures has the same planar size, but the other part of the semiconductor chip structures has different planar sizes. This disclosure is not limited.

In the step S04, the quantity of the circuited chip units is greater than one hundred, or further greater than one thousand.

In one embodiment, each of the semiconductor chip structure further includes a corresponding part of the process carrier 1, if the process carrier 1 is also cut for breaking within any one of the step S01 to S04. In an alternative embodiment, the step S04 further includes: removing the process carrier 1 from the semiconductor chip structures before the semiconductor chip structures are divided individually, wherein each of the semiconductor chip structure is defined excluding any corresponding part of the process carrier 1.

In the step S04, the corresponding one or each of the semiconductor chip structures includes a thin-film circuit.

In the step S04, the corresponding one or each of the semiconductor chip structures includes a transistor, which can be a thin-film transistor (TFT) or/and a Complementary Metal-Oxide-Semiconductor (CMOS) transistor.

In the step S04, the corresponding one or each of the semiconductor chip structures is a power management intergraded circuit (PMIC). In the step S04, the corresponding one or each of the semiconductor chip structures is a chip with a set of circuits or with a system of integrated circuits.

In summary, the method for fabricating semiconductor chip structures of this disclosure includes steps of: providing a plurality of slice units, each of which is made by a wafer, on a process carrier; accomplishing circuits on the slice units; and breaking down the circuited slice units to form a plurality of semiconductor chip structures individually with each other. Herein, the planar size of a corresponding one of the slice units is no less than the planar size of the corresponding one of the semiconductor chip structures, or the planar size of the corresponding one of the slice units is no less than multiple of the planar size of the corresponding one of the semiconductor chip structures. In addition, the semiconductor carrier and semiconductor chip structure can be made by the above-mentioned method. Accordingly, the method of this disclosure can fabricate the semiconductor carrier and the semiconductor chip structures in an effective and efficient manner. The present disclosure has the benefit of, but not objective-oriented as, variety of products, budget control of manufacture, requirements meeting of different application.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. A method for fabricating semiconductor chip structures, comprising:
providing a plurality of slice units tiled with one another on a surface of a process carrier, wherein each of the slice units is made by a wafer and includes a substrate with an outline, and a gap is formed between adjacent two of the slice units;
planarizing tops of the slice units;
accomplishing circuits on the slice units and turning the slice units into a plurality of circuited slice units; and
forming a plurality of semiconductor chip structures individually with each other by at least breaking down the circuited slice units; wherein a planar size of a corresponding one of the slice units is no less than a planar size of a corresponding one of the semiconductor chip structures, or the planar size of the corresponding one of the slice units is no less than multiple of the planar size of the corresponding one of the semiconductor chip structures.

2. The method of claim 1, wherein in the step of providing the slice units on the process carrier, wherein the substrate is a single-crystal silicon substrate, a poly-crystal silicon substrate, a SOI (silicon on insulator) substrate, a SiC (Silicon Carbide) substrate, a Sapphire substrate, a III-V compound substrate, an II-VI compound substrate, or a compound substrate.

3. The method of claim 1, wherein in the step of providing the slice units on the process carrier, wherein the process carrier is a glass substrate.

4. The method of claim 1, before the step of providing the plural of slice units on the process carrier, further comprising: cutting each of the slice units into a plural of chip units, and holding the outlines of the slice units kept, wherein a planar size of one of the chip units is equal to the planar size of the corresponding one of the semiconductor chip structures.

5. The method of claim 4, before the step of cutting each of the slice units into a plurality of chip units, further comprising: taping a film on a bottom face of each of the slice unit.

6. The method of claim 1, wherein in the step of providing the slice units on the process carrier, wherein the substrate of each of the slice units defines a thickness, which is greater than 0.4 mil (10 nm) or is no greater than 100 μm.

7. The method of claim 1, wherein in the step of forming the semiconductor chip structures, wherein each of the semiconductor chip structures further includes a corresponding part of the process carrier.

8. The method of claim 1, wherein in the step of forming the semiconductor chip structures, wherein the corresponding one of the semiconductor chip structures is a chip with a set of circuits or with a system of integrated circuits.

9. A semiconductor carrier, comprising:
a process carrier; and
a plurality of slice units connected on a surface of the process carrier and tiled with one another, wherein each of the slice units includes a substrate with an outline, and a gap is formed between adjacent two of the slice units;
wherein each of the slice units is made by a wafer, and a coefficient of thermal expansion (CTE) of the process carrier approaches a CTE of the substrate.

10. The semiconductor carrier of claim 9, wherein each of the slice units defines a circumscribed circle sharing a co-center with the wafer.

11. The semiconductor carrier of claim 9, further comprising an adhesive formed between the slice units and the process carrier.

12. The semiconductor carrier of claim 11, wherein the adhesive is made of PI (Polyimide).

13. The semiconductor carrier of claim 9, wherein the process carrier is made of glass.

14. The semiconductor carrier of claim 9, wherein in the step of providing the slice units on the process carrier, wherein the substrate of each of the slice units defines a thickness, which is greater than 0.4 mil or is no greater than 100 μm.

15. The semiconductor carrier of claim 9, wherein the substrate of each of the slice units is a bare substrate.

16. The semiconductor carrier of claim 9, wherein tops of the slice units are planarized.

17. The semiconductor carrier of claim 9, wherein the slice units are accomplished with circuits to be a plurality of circuited slice units.

18. The semiconductor carrier of claim 9, wherein one or more of the circuited slice units include a thin film circuit.

19. The semiconductor carrier of claim 9, wherein one or more of the circuited slice units include a transistor.

20. A semiconductor chip structure formed by turning the circuited slice units as recited in claim 17 into pieces individually with each other.
